(19) United States
(12) Patent Application Publication
(10) Pub. No.: US 2019/0129534 A1
(43) Pub. Date: May 2, 2019

(54) IN-CELL CAPACITIVE TOUCH PANEL

(71) Applicant: Raydium Semiconductor Corporation, Hsinchu (TW)

(72) Inventor: Chang-Ching CHIANG, Taichung City (TW)

(21) Appl. No.: 16/169,027

(22) Filed: Oct. 24, 2018

Related U.S. Application Data
(60) Provisional application No. 62/579,192, filed on Oct. 31, 2017.

(51) Int. Cl. G06F 3/044; G06F 3/042; H01L 27/32

(52) U.S. Cl. CPC G06F 3/044; H01L 27/323; G06F 3/042

(57) ABSTRACT

An in-cell capacitive touch panel applied to a passive matrix light-emitting diode (LED) display is disclosed. The in-cell capacitive touch panel includes a plurality of pixels and a first touch electrode. A laminated structure of each pixel includes a substrate, a first conductive layer, a second conductive layer, and a LED layer. The substrate is disposed at one side of the pixel. The first conductive layer is disposed above the substrate and arranged along a first direction. The second conductive layer is disposed above the first conductive layer and arranged along a second direction. The LED layer is disposed between overlapping regions of the first conductive layer and the second conductive layer to form the pixel. The first touch electrode is disposed between a first pixel and a second pixel of the plurality of pixels. The first pixel and the second pixel are adjacent.

### BACKGROUND OF THE INVENTION

### 1. Field of the Invention

The invention relates to a touch panel; in particular, to an in-cell capacitive touch panel.

### 2. Description of the Prior Art

In recent years, organic light-emitting diode displays have been widely used in various mobile devices and micro-displays, which can be divided into active matrix organic light-emitting diode (AMOLED) displays and passive matrix organic light-emitting diode (PMOLED) displays according to different driving methods. Compared with the active matrix organic light emitting diode display, the passive matrix organic light emitting diode display has a lower manufacturing cost because of its simpler driving circuit substrate structure. As shown in FIG. 1, the cathode electrode CE and the anode electrode AE of the passive matrix organic light-emitting diode display are alternately arranged in the horizontal direction and the vertical direction to form an overlapping region of a plurality of cathode electrodes CE and anode electrodes AE. A pixel can be formed by disposing the organic light emitting diode layer OLED in the overlapping regions. The cathode driver CD and the anode driver AD respectively select a specific cathode electrode CE and an anode electrode AE and apply a voltage to drive luminescence of the luminescent pixels located in the overlapping region of the cathode electrode CE and the anode electrode AE.

Next, please refer to FIG. 1A˜FIG. 1C. FIG. 1A˜FIG. 1C are schematic cross-sectional views showing different laminated structures taken along the line AA′ in FIG. 1, respectively.

As shown in FIG. 1A, the cathode electrode CE is disposed above the substrate SUB; the organic light emitting diode layer OLED1 is disposed above the cathode electrode CE; and the organic light emitting diode layer OLED1 may be red (R), green (G) or blue (B). The organic light-emitting diode is composed of an anode electrode AE and an encapsulation layer ENC arranged in this order.

As shown in FIG. 1B, the cathode electrode CE is disposed above the substrate SUB; the organic light emitting diode layer OLED2 is disposed above the cathode electrode CE; and the organic light emitting diode layer OLED2 may be formed of a white organic light emitting diode and sequentially disposed above there are an anode electrode AE, a color filter CF of a different color and an encapsulation layer ENC.

As shown in FIG. 1C, the cathode electrode CE is disposed above the substrate SUB; the organic light emitting diode layer OLED3 is disposed above the cathode electrode CE; and the organic light emitting diode layer OLED3 may be red (R), green (G) or blue (B). The organic light-emitting diode is configured and provided with an anode electrode AE, a color conversion layer CC, and an encapsulation layer ENC in this order.

However, the passive matrix OLED display described above can only provide a display function. In order to provide a touch function, it is usually required to use an external touch sensing module, which not only increases the overall display, but also the thickness causes a drop in production yield, resulting in a significant increase in production costs.

As for micro light-emitting diode, it is a new type of display technology. As its name suggests, its size is smaller than that of the conventional light-emitting diode. It can usually be less than 100 um or even as small as Sum, so it has the ability to realize the display panel with high pixels per inch (PPI).

In the process of the micro light-emitting diode display, red (R), green (G) and blue (B) inorganic LEDs can be separately formed on different epitaxial substrates, and then the specific transfer technique moves it from the epitaxial substrate to a drive circuit substrate (e.g., a glass substrate) and bonds it to a specific position on the drive circuit substrate. For example, as shown in FIG. 2A˜FIG. 2F, the micro light-emitting diode MLED can be sucked from the epitaxial substrate SUB1 by means of electromagnetic force, vacuum suction, van der Waals force, etc. through a special micro-clipper CP. Thereafter, the micro light-emitting diode MLED is transferred to the glass substrate SUB2 and bonded to a specific position on the glass substrate SUB2.

Since the inorganic light-emitting diode has high luminous efficiency characteristics, compared to the organic light-emitting diode, the micro light-emitting diode can emit the same or even higher brightness under a relatively small pixel light-emitting area. For example, the luminance of the organic light-emitting diode is up to about 1000 nits, and the luminance of the inorganic light-emitting diode can be as high as 106 nits, that is, the luminance of the inorganic light-emitting diode can be 1000 times that of the organic light-emitting diode.

In this case, the brightness of the micro light-emitting diode and the organic light-emitting diode can be equal when the size of the pixel light-emitting region of the micro light-emitting diode is only 25 um² (that is, 5 um*5 um), and the pixel illuminating region of the organic light-emitting diode is 25000 um² (that is, 158 um*158 um). Therefore, if the micro light-emitting diode display and the organic light-emitting diode display have the same pixel density and unit brightness, there will be a lot of free space without the light-emitting diode layer, the anode, the cathode and traces on the drive circuit substrate of the miniature light-emitting diode display, and the free space can be used to dispose other circuits and traces without affecting the original circuit layout of the display.

From above, it can be found that if the passive matrix organic light emitting diode display uses both organic light-emitting diode (OLED) and micro light-emitting diode (Micro LED) technology, as shown in FIG. 3, a part of the overlapping area of the cathode electrode CE and the anode electrode AE is still provided with an organic light-emitting diode OLED, and another part of the overlapping area of the cathode electrode CE and the anode electrode AE is provided with a micro light-emitting diode MLED. In this way, since the size of the micro light-emitting diode MLED is small, the gap area SA between the adjacent two electrodes in FIG. 3 is larger than the gap area SA between the adjacent two electrodes in FIG. 1. Therefore, the gap area SA between the adjacent two electrodes in FIG. 3 can be used to dispose other circuits and traces without affecting the original circuit layout of the display.

### SUMMARY OF THE INVENTION

Therefore, the invention provides an in-cell capacitive touch panel to solve the above-mentioned problems of the prior arts.

A preferred embodiment of the invention is an in-cell capacitive touch panel. In this embodiment, the in-cell capacitive touch panel applied to a passive matrix light-emitting diode display is disclosed. The in-cell capacitive touch panel includes a plurality of pixels and a first touch electrode. A laminated structure of each pixel includes a substrate, a first conductive layer, a second conductive layer, and a light-emitting diode layer. The substrate is disposed at one side of the pixel. The first conductive layer is disposed above the substrate and arranged along a first direction. The second conductive layer is disposed above the first conductive layer and arranged along a second direction. The light-emitting diode layer is disposed between overlapping regions of the first conductive layer and the second conductive layer to form the pixel. The first touch electrode is disposed between a first pixel and a second pixel of the plurality of pixels. The first pixel and the second pixel are adjacent.

In an embodiment, the laminated structure further includes an encapsulation layer and an insulating layer. The encapsulation layer is disposed on another side of the pixel opposite to the substrate. The insulating layer is filled between the encapsulation layer and the substrate.

In an embodiment, the in-cell capacitive touch panel further includes a second touch electrode disposed between the first pixel and a third pixel of the plurality of pixels, wherein the first pixel and the second pixel are adjacent to each other along the second direction, and the first pixel and the third pixel are adjacent to each other along the first direction.

In an embodiment, the first touch electrode and the second touch electrode are disposed between the encapsulation layer and the substrate, and the second touch electrode is disposed above the first touch electrode and the first conductive layer, the first touch electrode and the second conductive layer are separated by the insulating layer and the second touch electrode and the first conductive layer are separated by the insulating layer.

In an embodiment, the first touch electrode and the second touch electrode are electrically connected through a via to form a mesh structure or a comb structure.

In an embodiment, the first touch electrode and the second touch electrode are disposed between the encapsulation layer and the substrate, and the first touch electrode and the second touch electrode are formed of the same conductive layer and electrically connected to each other, the first touch electrode and the second touch electrode are separated from the second conductive layer and the first conductive layer through the insulating layer.

In an embodiment, the first pixel and the second pixel are adjacent to each other along the first direction or the second direction, and the first touch electrode is disposed between the encapsulation layer and the substrate.

In an embodiment, the first touch electrode and the first conductive layer are formed of the same conductive layer and separated from each other through the insulating layer.

In an embodiment, the first touch electrode and the second conductive layer are formed of the same conductive layer and separated from each other through the insulating layer.

In an embodiment, the first touch electrode is formed of a conductive layer different from the first conductive layer and the second conductive layer and the first touch electrode is separated from the first conductive layer and the second conductive layer through the insulating layer.

In an embodiment, a plurality of first touch electrodes are arranged as an one-dimensional self-capacitive touch sensing electrode group having a specific pattern to determine a touch position through a self-capacitance sensed by a first touch electrode or a ratio of the self-capacitances sensed by two adjacent first touch electrodes.

In an embodiment, the light emitting diode layer is formed of an organic light-emitting diode (OLED) in each of the plurality of pixels.

In an embodiment, the light emitting diode layer is formed of an organic light-emitting diode (OLED) in each of the plurality of pixels.

In an embodiment, the light emitting diode layer is formed of an organic light-emitting diode (OLED) in a part of the plurality of pixels, and the light emitting diode layer is formed of a micro light-emitting diode (Micro LED) in another part of the plurality of pixels.

In an embodiment, the first conductive layer forms a plurality of first polarity electrodes arranged in parallel, and the plurality of first polarity electrodes are coupled to a first polarity driver, the first touch electrode is disposed in a gap between two first polarity electrodes of the plurality of first polarity electrodes.

In an embodiment, the second conductive layer forms a plurality of second polarity electrodes arranged in parallel, and the plurality of second polarity electrodes are coupled to a second polarity driver, the second touch electrode is disposed in a gap between two second polarity electrodes of the plurality of second polarity electrodes.

In an embodiment, the first touch electrode and the first conductive layer are formed of the same conductive layer or different conductive layers.

In an embodiment, the second touch electrode and the second conductive layer are formed of the same conductive layer or different conductive layers.

In an embodiment, a mutual-capacitive touch sensing technology or a self-capacitive touch sensing technology is applied to the in-cell capacitive touch panel.

In an embodiment, the light emitting diode layer has a top-emitting light-emitting diode structure, a bottom-emitting light-emitting diode structure or a double-sided light-emitting diode structure.

In an embodiment, a touch sensing mode and a display mode of the in-cell capacitive touch panel are driven in a time-dividing way, so that a touch sensing period and a display period of the in-cell capacitive touch panel do not overlap each other.

In an embodiment, when the in-cell capacitive touch panel operates under the touch sensing mode in a blanking interval out of the display period, the first conductive layer or the second conductive layer of the pixel is maintained at a fixed voltage.

In an embodiment, the blanking interval includes at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval includes the vertical blanking interval.

In an embodiment, the touch sensing period and the display period of the in-cell capacitive touch panel are at least partially overlapped.

In an embodiment, when the in-cell capacitive touch panel is synchronized with a horizontal sync signal or a vertical sync signal or operates under the touch sensing mode in a blanking interval out of the display period, the first conductive layer or the second conductive layer of the pixel is maintained at a fixed voltage.

In an embodiment, the blanking interval includes at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval includes the vertical blanking interval.

In an embodiment, the in-cell capacitive touch panel is coupled to a touch controller and a display controller respectively, and the touch controller is synchronized with the display controller to adjust a timing of touch and display operations.

In an embodiment, the in-cell capacitive touch panel is coupled to a touch display controller, and the touch display controller is formed by integrating a touch control and a display controller to adjust a timing of touch and display operations.

Compared to the prior art, the in-cell capacitive touch panel of the invention is suitable for a passive matrix organic light-emitting diode display, and can effectively integrate display and touch functions, and the in-cell capacitive touch panel of the invention has the following advantages:

(1) The design of the touch sensing electrode and its traces is relatively simple, and can be applied to mutual-capacitive touch sensing technology or self-capacitive touch sensing technology.

(2) The original conductive layer in the panel can be used as touch electrodes to reduce the complexity of manufacturing process and the manufacturing cost.

(3) The overlapping area of the touch sensing electrode and the display driving electrode is relatively small, which can effectively reduce the RC loading of the panel and reduce noise.

(4) The touch sensing electrode system is disposed between pixels, so the display area of the pixel is not blocked, and the influence on the visibility of the panel can be reduced.

(5) Touch and display can be driven in a time-dividing way to improve the signal-to-noise ratio.

The advantage and spirit of the invention may be understood by the following detailed descriptions together with the appended drawings.

### BRIEF DESCRIPTION OF THE APPENDED DRAWINGS

FIG. 1 illustrates a schematic diagram of a conventional passive matrix organic light emitting diode display.

FIG. 1A˜FIG. 1C illustrate cross-sectional views of different laminated structures taken along the line AA′ in FIG. 1 respectively.

FIG. 2A˜FIG. 2F illustrate schematic diagrams of the process of transferring a micro-light emitting diode from an epitaxial substrate to a glass substrate through a special micro-clipper.

FIG. 3 illustrates a schematic diagram showing a passive matrix type organic light emitting diode display capable of simultaneously using an organic light-emitting diode (OLED) and a micro light-emitting diode (Micro LED) technology.

FIG. 4 illustrates a schematic diagram of an in-cell capacitive touch panel according to a preferred embodiment of the invention.

FIG. 5 illustrates a cross-sectional view of the laminated structure taken along the line BB′ in FIG. 4.

FIG. 6 illustrates a schematic diagram of an in-cell capacitive touch panel according to another preferred embodiment of the invention.

FIG. 7 illustrates a cross-sectional view of the laminated structure taken along the line CC′ in FIG. 6.

FIG. 8 illustrates a schematic diagram of an in-cell capacitive touch panel according to still another preferred embodiment of the invention.

FIG. 9 illustrates a cross-sectional view of the laminated structure taken along the section line DD′EE′ in FIG. 8.

FIG. 10 illustrates a schematic diagram of an in-cell capacitive touch panel according to still another preferred embodiment of the invention.

FIG. 11˜FIG. 13 illustrate timing diagrams of the vertical sync signal Vsync, the horizontal sync signal Hsync, and the touch sensing drive signal STH of the in-cell capacitive touch panel in different embodiments.

FIG. 14 illustrates a schematic diagram of the display and touch operations of the in-cell capacitive touch panel separately controlled by the display driver DD and the touch driver TD.

FIG. 15 illustrates a schematic diagram of the display and touch operations of the in-cell capacitive touch panel controlled by the touch display integrated driver (TDID).

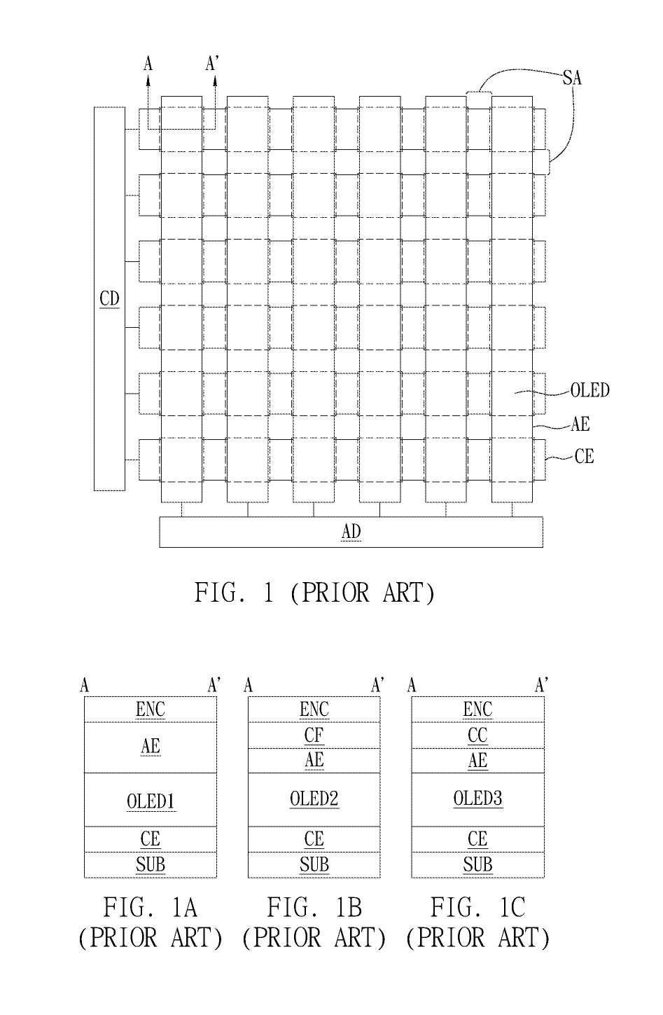

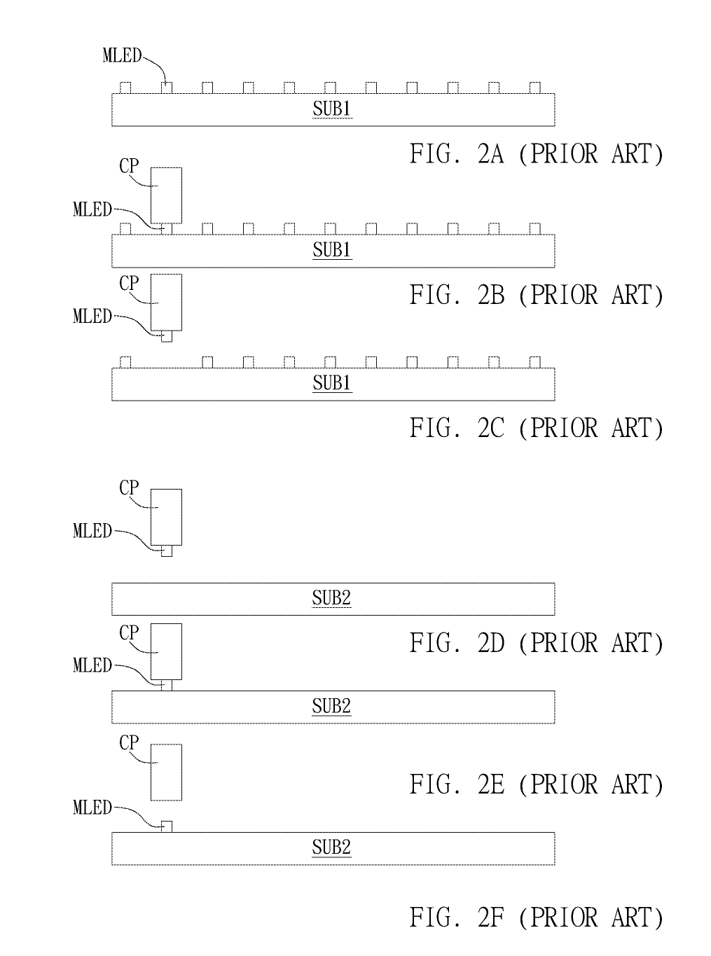

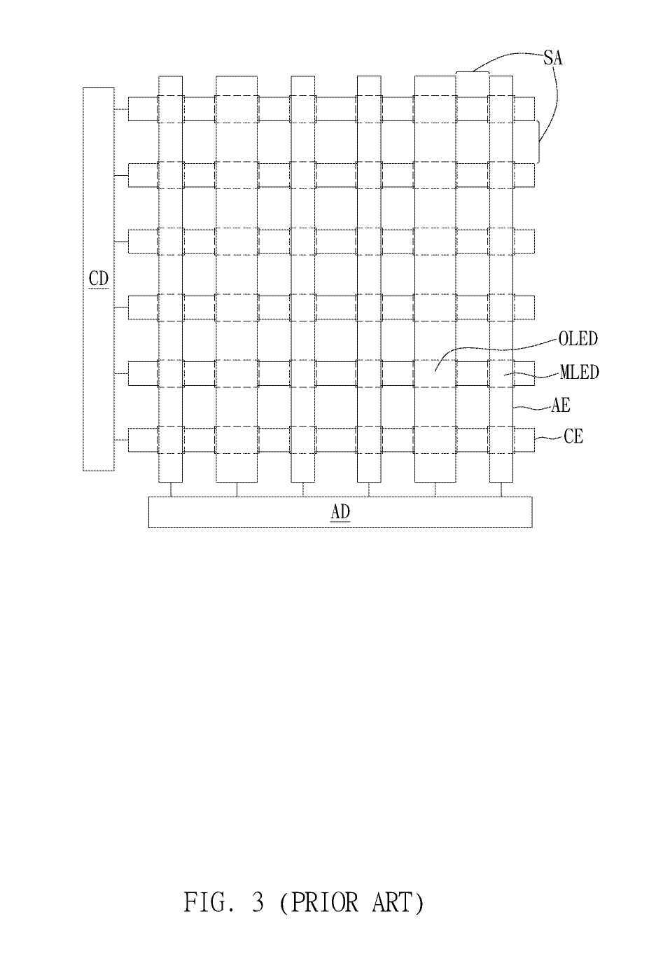

### DETAILED DESCRIPTION OF THE INVENTION

A preferred embodiment of the invention is an in-cell capacitive touch panel. In this embodiment, the in-cell capacitive touch panel applied to a passive matrix light-emitting diode display is disclosed. The in-cell capacitive touch panel includes a plurality of pixels and a first touch electrode. A laminated structure of each pixel includes a substrate, a first conductive layer, a second conductive layer, and a light-emitting diode layer. The substrate is disposed at one side of the pixel. The first conductive layer is disposed above the substrate and arranged along a first direction. The second conductive layer is disposed above the first conductive layer and arranged along a second direction. The light-emitting diode layer is disposed between overlapping regions of the first conductive layer and the second conductive layer to form the pixel. The first touch electrode is disposed between a first pixel and a second pixel of the plurality of pixels. The first pixel and the second pixel are adjacent.

In fact, the in-cell capacitive touch panel can further include a second touch electrode disposed between the first pixel and a third pixel of the plurality of pixels, wherein the first pixel and the second pixel are adjacent to each other along the second direction, and the first pixel and the third pixel are adjacent to each other along the first direction.

Next, the detailed technical content of the invention will be described through different preferred embodiments.

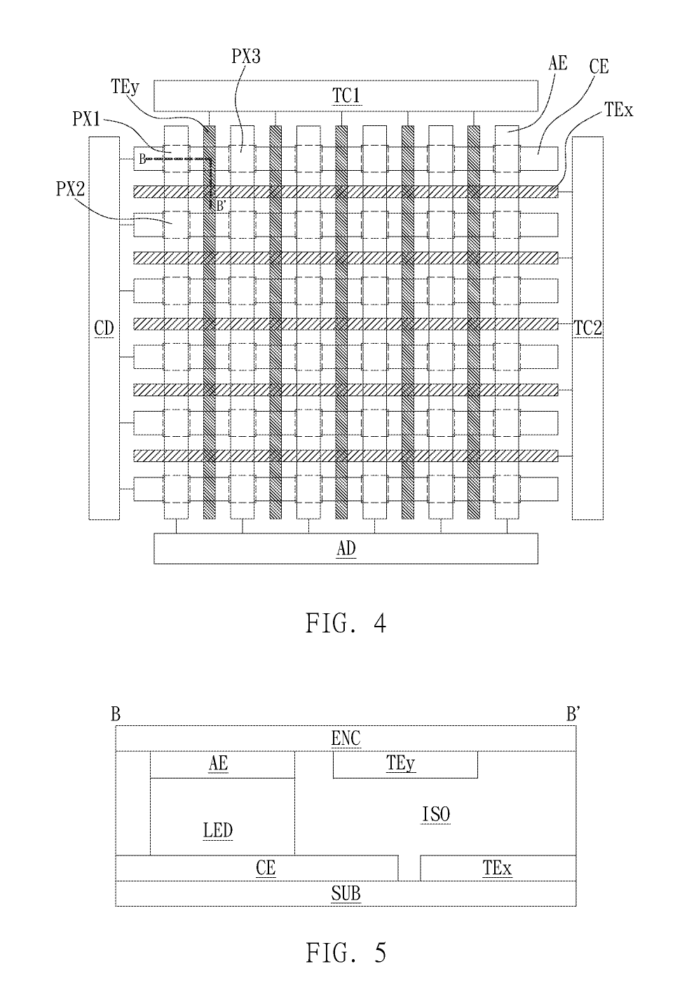

Please refer to FIG. 4 and FIG. 5. FIG. 4 illustrates a schematic diagram of an in-cell capacitive touch panel according to a preferred embodiment of the invention; FIG. 5 illustrates a cross-sectional view of the laminated structure taken along the line BB′ in FIG. 4.

As shown in FIG. 4, a plurality of cathode electrodes CE (that is, first polarity electrodes formed of the first conductive layer) and a plurality of anode electrodes AE (that is, second polarity electrodes formed of the second conductive layer) arranged in parallel along the horizontal direction (e.g., the first direction) and the vertical direction (e.g., the second direction) respectively, and the cathode electrodes CE and the anode electrodes AE overlap each other to form overlap regions of the cathode electrodes CE and the anode electrodes AE. And, the LEDs can be formed in the overlap regions to form a plurality of pixels including a first pixel PX1˜a third pixel PX3. In general, the light-emitting diode layer LED can include an electron transport layer (ETL), a hole transport layer (HTL), an electron injection layer (EIL), a hole injection layer (HIL) and an organic light emitting layer (OEL), but Not limited to this.

The first touch electrodes TEx are respectively arranged in parallel along the horizontal direction (e.g., the first direction) in a gap between two adjacent cathode electrodes CE (e.g., the first polarity electrodes), that is, the first touch electrode TEx can be disposed in a gap between the first pixel PX1 and the second pixel PX2 of the pixels, and the first pixel PX1 and the second pixel PX2 are adjacent to each other along the vertical direction (e.g., the second direction). Similarly, the second touch electrodes TEy are respectively arranged in parallel along the vertical direction (e.g., the second direction) in a gap between two adjacent anode electrodes AE (e.g., the second polarity electrodes), that is, the second touch electrode TEy can be disposed in a gap between the first pixel PX1 and the third pixel PX3 of the pixels, and the first pixel PX1 and the third pixel PX3 are adjacent to each other along the horizontal direction (e.g., the first direction).

In this embodiment, the cathode electrodes CE (e.g., the first polarity electrodes) are coupled to a cathode driver CD and controlled by the cathode driver CD; the anode electrodes AE (e.g., the second polarity electrodes) is coupled to an anode driver AD and controlled by the anode driver AD. The first touch electrodes TEx are coupled to a second touch controller TC2 and controlled by the second touch controller TC2; the second touch electrodes TEy are coupled to a first touch controller TC1 and are controlled by the first touch controller TC1.

As shown in FIG. 5, the laminated structure obtained along the cross-sectional line BB′ in FIG. 4 includes the substrate SUB, the cathode electrode CE (e.g., the first polarity electrode), the light-emitting diode layer LED, the anode electrode AE (e.g., the second polarity electrode), the first touch electrode TEx, the second touch electrode TEy, the encapsulation layer ENC and the insulating layer ISO.

The substrate SUB is disposed on one side of the first pixel PX1, and the encapsulation layer ENC is disposed on another side of the first pixel PX1 opposite to the substrate SUB. The cathode electrode CE (e.g., the first polarity electrode) is disposed above the substrate SUB and arranged along the horizontal direction (e.g., the first direction). The anode electrode AE (e.g., the second polarity electrode) is disposed above the cathode electrode CE and arranged along the vertical direction (e.g., the second direction). The light-emitting diode layer LED is disposed between the region where the cathode electrode CE and the anode electrode AE overlap each other to form the first pixel PX1.

The first touch electrode TEx and the second touch electrode TEy are disposed between the encapsulation layer ENC and the substrate SUB, and the second touch electrode TEy is disposed above the first touch electrode TEx and the cathode electrode CE. The insulating layer ISO is filled between the encapsulation layer ENC and the substrate SUB for separating the first touch electrode TEx and the cathode electrode CE, the second touch electrode TEy and the anode electrode AE, the first touch electrode TEx and the second Touch electrode TEy. That is to say, the first touch electrode TEx is separated from the anode electrode AE through the insulating layer ISO and the second touch electrode TEy is separated from the cathode electrode through the insulating layer ISO.

In this embodiment, the first touch electrode TEx and the cathode electrode CE can be made of the same first conductive layer to simplify the overall manufacturing process, or the first touch electrode TEx and the cathode electrode CE can be made of different conductive layers. The first touch electrode TEx and the cathode electrode CE are separated by the insulating layer ISO to increase the yield and reduce the RC loading.

Similarly, the second touch electrode TEy and the anode electrode AE can be made of the same second conductive layer to simplify the overall manufacturing process, or the second touch electrode TEy and the anode electrode AE can be made of different conductive layers. The second touch electrode TEy and the anode electrode AE are separated by the insulating layer ISO to increase the yield and reduce the RC loading.

In practical applications, the LED layer can be formed by an organic light-emitting diode (OLED) or a micro LED, and the LED layer is disposed on the overlap region that the cathode electrode CE (e.g., the first conductive layer) and the anode electrode AE (e.g., the second conductive layer) overlap each other.

When the LED layer is formed by micro light-emitting diodes, the LED layer can be flip-chip mounted and coupled to conductive contacts of the cathode electrode CE (e.g., the first conductive layer) and the anode electrode AE (e.g., the second conductive layer) through the cathode contacts and the anode contacts respectively, to form electrical connections.

In practical applications, the first touch electrode TEx arranged along the horizontal direction (e.g., the first direction) and the second touch electrode TEy arranged along the vertical direction (e.g., the second direction) can be separated by the insulation layer ISO. The first touch electrode TEx and the second touch electrode TEy can be driven as a transmitter (TX) electrode and a receiver (RX) electrode respectively.

For example, the first touch electrode TEx can be driven as the transmitter (TX) electrode and the second touch electrode TEy can be driven as the receiver (RX) electrode, or the first touch electrode TEx can be driven as the receiver (RX) electrode and the second touch electrode TEy can be driven as the transmitter (TX) electrode.

It should be noted that in order to form the transmitter (TX) electrode or the receiver (RX) electrode having large area to improve capacitance sensing capability, a plurality of transmitter (TX) electrodes or a plurality of receivers (RX) electrodes can be coupled to each other out of the display area of the in-cell capacitive touch panel, or coupled to each other in the touch controller (e.g., the first touch controller TC1 or the second touch controller TC2) to form the transmitter (TX) electrode or the receiver (RX) electrode having large area, but not limited to this.

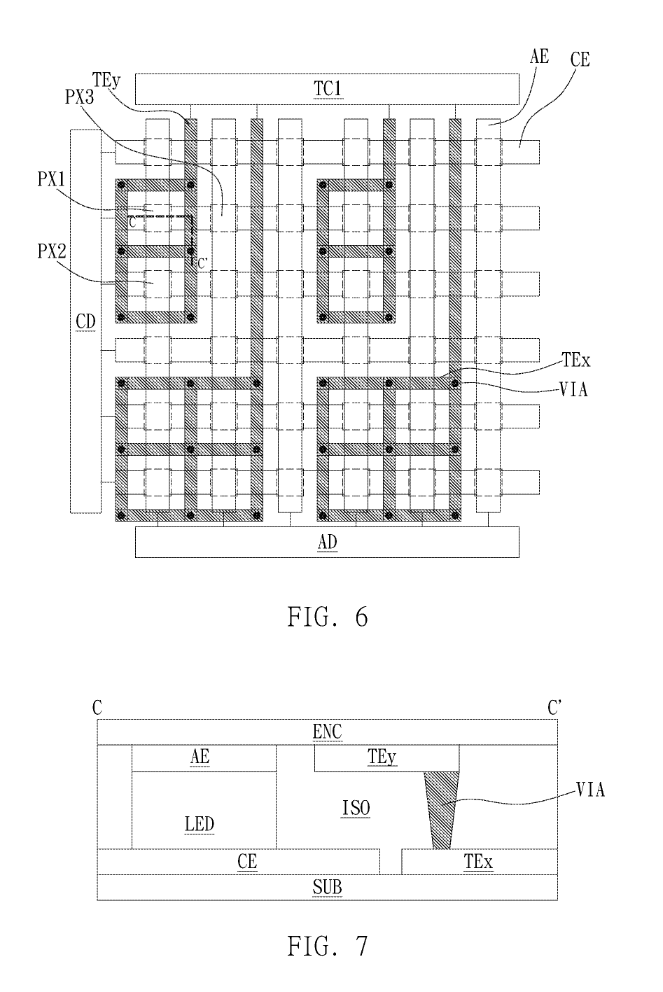

Next, please refer to FIG. 6 and FIG. 7. FIG. 6 illustrates a schematic diagram of an in-cell capacitive touch panel according to another preferred embodiment of the invention; FIG. 7 illustrates a cross-sectional view of the laminated structure taken along the line CC′ in FIG. 6.

As shown in FIG. 6, the cathode electrodes CE (e.g., the first conductive layer) and the anode electrodes AE (e.g., the second conductive layers) are arranged in parallel along the horizontal direction (e.g., the first direction) and the vertical direction. (e.g., the second direction) respectively and alternately overlap each other to form an overlap region of the cathode electrodes CE (e.g., the first conductive layers) and the anode electrodes AE (e.g., the second conductive layers), and then the light-emitting diode layer LED (e.g., the OLED or the micro LED) is disposed in the overlapping regions to form a plurality of pixels including the first pixel PX1˜the third pixel PX3.

The first touch electrodes TEx are respectively arranged in parallel along the horizontal direction (e.g., the first direction) in the gap between two adjacent cathode electrodes CE (e.g., the first conductive layer), that is to say, the first touch electrode TEx is disposed in the gap between the first pixel PX1 and the second pixel PX2 of the pixels, and the first pixel PX1 and the second pixel PX2 are adjacent to each other along the vertical direction (e.g., the second direction).

Similarly, the second touch electrodes TEy are respectively arranged in parallel along the vertical direction (e.g., the second direction) in a gap between two adjacent anode electrodes AE (e.g., the second conductive layers), that is to say, the second touch electrode TEy is disposed in the gap between the first pixel PX1 and the third pixel PX3 of the pixels, and the first pixel PX1 and the third pixel PX3 are adjacent to each other along the horizontal direction (e.g., the first direction).

It should be noted that the overlap regions of the first touch electrodes TEx and the second touch electrodes TEy can be electrically connected to each other through vias to form a mesh structure or a comb structure to form the mutual capacitive touch sensing electrode or the self-capacitive touch sensing electrode through suitable configuration, but not limited to this.

The cathode electrodes CE (e.g., the first conductive layer) are coupled to the cathode driver CD and controlled by the cathode driver CD; the anode electrodes AE (e.g., the second conductive layer) are coupled to the anode driver AD and controlled by the anode driver AD. The first touch electrodes TEx are coupled to the second touch controller TC2 and controlled by the second touch controller TC2; the second touch electrodes TEy are coupled to the first touch controller TC1 and controlled by the first touch controller TC1.

As shown in FIG. 7, the laminated structure obtained along the cross-sectional line CC′ in FIG. 6 includes a substrate SUB, a cathode electrode CE, a light-emitting diode layer LED, an anode electrode AE, a first touch electrode TEx, and a second touch electrode TEy and an encapsulation layer ENC. The substrate SUB is disposed on one side of the first pixel PX1. The encapsulation layer ENC is disposed on another side of the first pixel PX1 opposite to the substrate SUB. The cathode electrodes CE (e.g., the first conductive layers) are disposed above the substrate SUB and arranged along the horizontal direction (e.g., the first direction). The anode electrode AE (e.g., the second conductive layer) is disposed above the cathode electrode CE (e.g., the first conductive layer) and arranged along the vertical direction (e.g., the second direction). The light-emitting diode layer LED is disposed on the overlap region of the cathode electrode CE (e.g., the first conductive layer) and the anode electrode AE (e.g., the second conductive layer) to form the first pixel PX1.

When the first touch electrode TEx and the second touch electrode TEy are respectively formed by different conductive layers and separated from each other by the insulating layer ISO, a part of the first touch electrodes TEx and a part of the second touch electrodes TEy can be electrically connected through the via to form a mesh structure, thereby increasing the capacitive coupling amount with the external touch object, and forming a mutual capacitive touch sensing electrode or a self-capacitive touch sensing electrode by an appropriate configuration, but not limited to this.

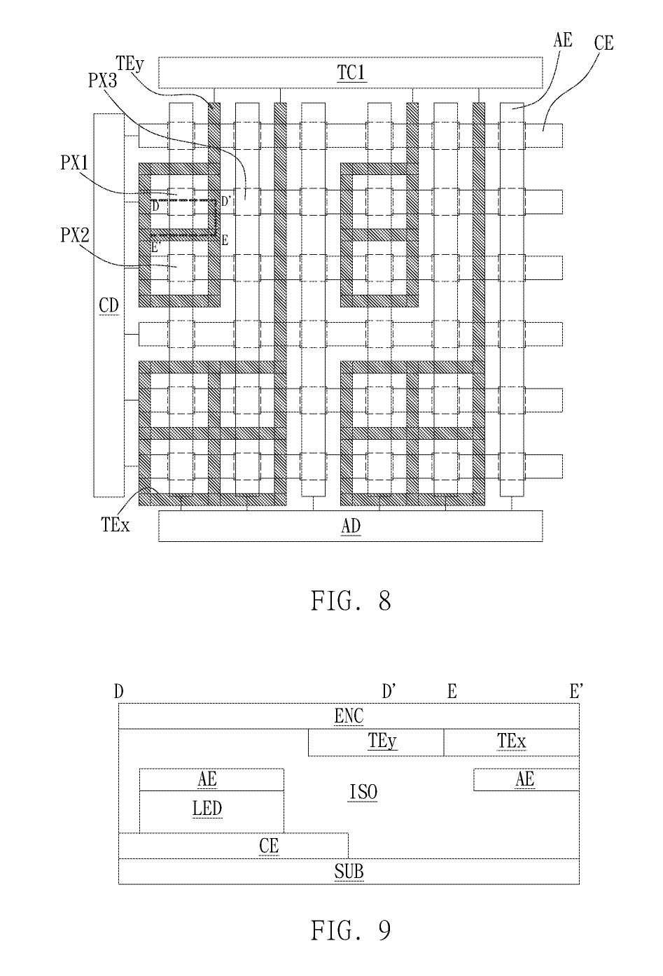

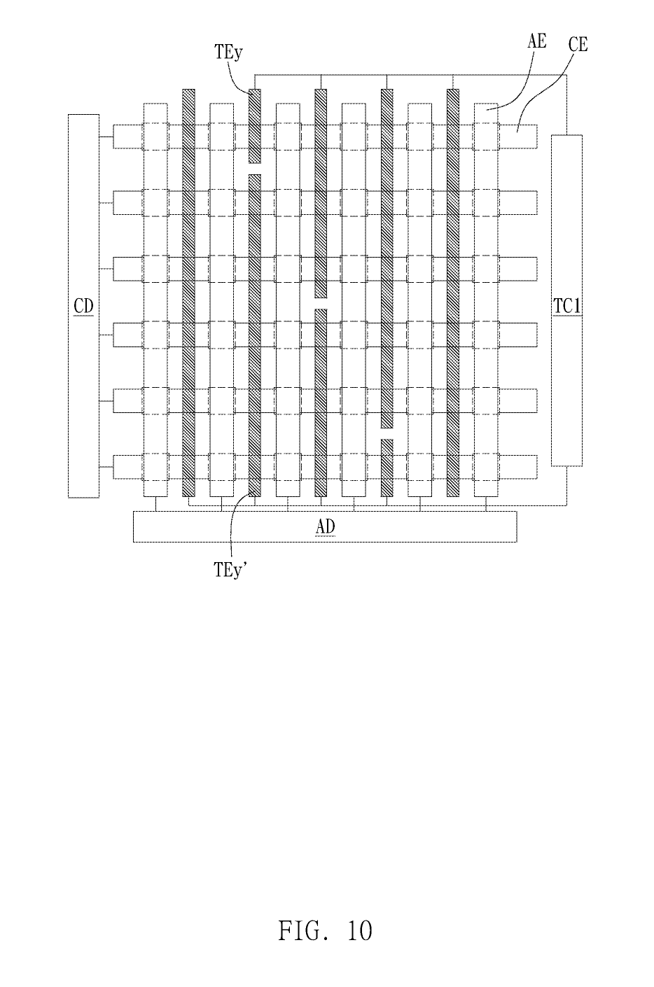

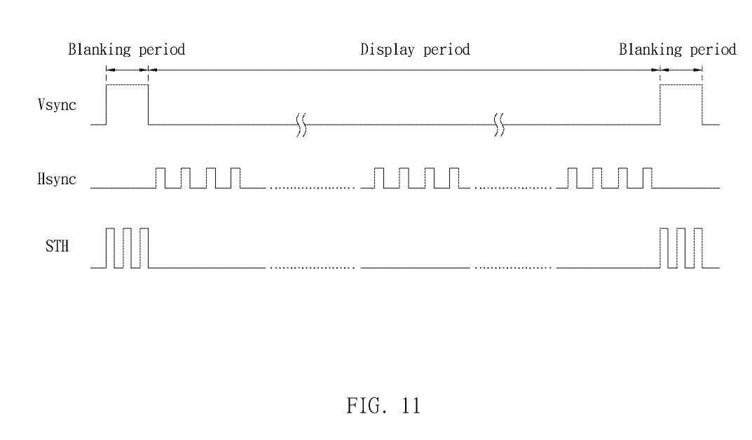

Please refer to FIG. 8 and FIG. 9. FIG. 8 illustrates a schematic diagram of an in-cell capacitive touch panel according to still another preferred embodiment of the invention; FIG. 9 illustrates a cross-sectional view of the laminated structure taken along the section line DD′EE′ in FIG. 8.

Different from the foregoing embodiment, the first touch electrode TEx and the second touch electrode TEy in this embodiment are formed of the same conductive layer, and the first touch electrode TEx and the second touch electrode TEy are separated from the cathode electrode CE or the anode electrode AE through the insulation layer ISO. The first touch electrodes TEx and the second touch electrodes TEy can be electrically connected to each other to form a mesh structure or a comb structure, and they can be suitablely configured to form the layout mutual capacitance touch sensing electrode or the self-capacitance touch sensing electrode, but not limited to this.

In addition, the touch sensing electrodes of the in-cell capacitive touch panel can be arranged only in a single direction (e.g., the horizontal direction or the vertical direction), and the touch sensing electrodes can be the first conductive layer (the same as the cathode electrode CE), the second conductive layer (the same as the anode electrode AE) or other conductive layers different from the cathode electrode CE and the anode electrode AE without specific limitations. In fact, the touch sensing electrodes can be respectively disposed in a gap between two adjacent anode electrodes AE arranged in parallel along the vertical direction, or a gap between two adjacent cathode electrodes CE arranged in parallel along the horizontal direction to reduce the RC loading and signal interference of the in-cell capacitive touch panel.

In practical applications, the first touch sensing electrodes arranged in a single direction can be arranged as a one-dimensional self-capacitance touch sensing electrode group having a specific pattern (e.g., a triangle or a trapezoid) to determine a touch position through a self-capacitance sensed by a first touch electrode or a ratio of the self-capacitances sensed by two adjacent first touch electrodes.

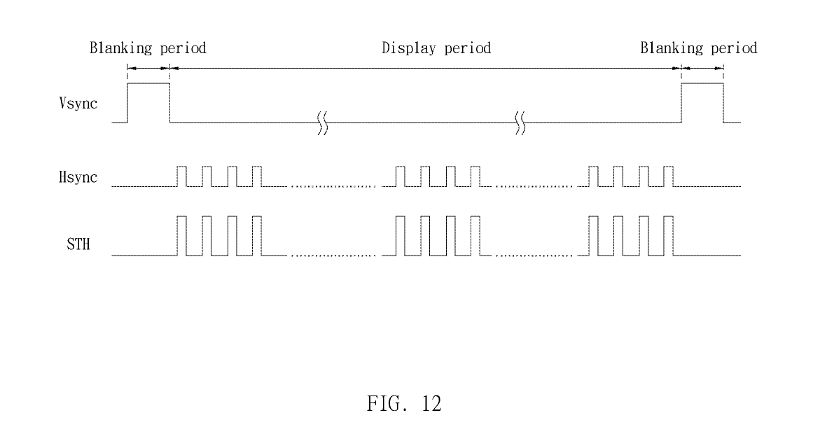

For example, as shown in FIG. 10, the touch sensing electrodes of the in-cell capacitive touch panel include only second touch electrodes TEy and TEy′ arranged in parallel along the vertical direction without touch electrodes arranged along the horizontal direction or any other directions. In this embodiment, the second touch electrodes TEy and TEy′ are respectively coupled to the first touch controller TC1 and controlled by the first touch controller TC1, and the second touch electrodes TEy and TEy′ are configured as a one-dimensional self-capacitance touch sensing electrode with a triangular or trapezoidal shape, and can determine a touch position through a self-capacitance sensed by a first touch electrode or a ratio of the self-capacitances sensed by two adjacent first touch electrodes.

In the above embodiments, the light emitting diode layer LED is formed of an organic light-emitting diode (OLED) in each of the plurality of pixels, the light emitting diode layer LED is formed of a micro light-emitting diode (micro LED) in each of the plurality of pixels, or the light emitting diode layer is formed of an organic light-emitting diode (OLED) in a part of the plurality of pixels, and the light emitting diode layer is formed of a micro light-emitting diode (Micro LED) in another part of the plurality of pixels.

It should be noted that when some or all of the pixels of the in-cell capacitive touch panel use micro light-emitting diodes to form the light-emitting diode layer LED, since the micro light-emitting diode requires only a small area to provide the same luminous intensity as that of the organic light-emitting diode having a large area can be achieved. Therefore, the pixels of the micro light-emitting diode can greatly reduce the used area, so that the layout space in the in-cell capacitive touch panel can be increased and used for disposing other circuits or traces. For example, the capacitive touch sensing electrode can increase the area by using the increased layout space, so that a higher capacitive coupling amount can be achieved to improve the touch sensing performance of the in-cell capacitive touch panel.

In the above embodiments, the cathode electrode and the anode electrode can be mutually adjusted according to different LED structure designs without affecting the embodiments of the invention. In addition, although the light-emitting diodes of the above embodiments are all exemplified by top-emitting LEDs, in fact, bottom-emitting LEDs or double-sided penetration LEDs can be also used without specific limitations.

It should be noted that the touch sensing mode and the display mode of the in-cell capacitive touch panel of the invention can be driven in a time-dividing way, so that the touch sensing period and the display period of the in-cell capacitive touch panel do not overlap each other, but not limited to this.

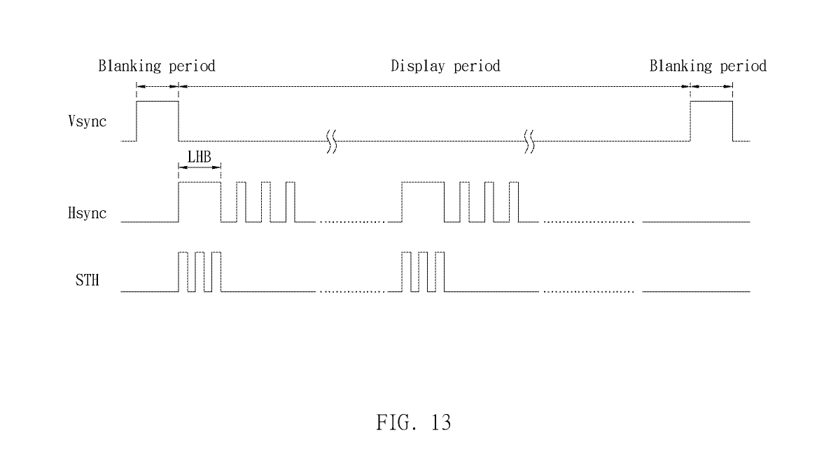

Please refer to FIG. 11˜FIG. 13. FIG. 11˜FIG. 13 respectively illustrate timing diagrams of the vertical sync signal Vsync, the horizontal sync signal Hsync and the touch sensing drive signal STH of the in-cell capacitive touch panel in different embodiments.

In an embodiment, the in-cell capacitive touch panel of the invention can operate in the touch sensing mode in a blanking interval out of the display period. In fact, the blanking interval can include at least one of a vertical blanking interval, a horizontal blanking interval and a long horizontal blanking interval. Wherein, the time length of the long horizontal blanking interval is equal to or longer than the time length of the horizontal blanking interval; the long horizontal blanking interval is obtained by redistributing the plurality of horizontal blanking intervals or the long horizontal blanking interval includes the vertical blanking interval.

For example, as shown in FIG. 11, the touch sensing driving signal STH is operated in the blanking interval of the vertical synchronization signal Vsync. At this time, the cathode electrode CE formed by the first conductive layer or the anode electrode AE formed by the second conductive layer can be maintained at a fixed voltage, but not limited to this.

In another embodiment, the touch sensing of the in-cell capacitive touch panel in the invention can also be performed in the display interval of the display period, and it can be synchronized with the horizontal synchronization signal Hsync or the vertical synchronization signal Vsync. For example, as shown in FIG. 12, the touch sensing driving signal STH is operated in the display interval of the display period, and the touch sensing driving signal STH is synchronized with the horizontal synchronization signal Hsync. At this time, the cathode electrode CE formed of the first conductive layer or the anode electrode AE formed of the second conductive layer can be maintained at a fixed voltage, but not limited to this.

In another embodiment, the touch sensing of the in-cell capacitive touch panel of the invention can be also operated in the touch sensing mode in a blanking interval of the display period. For example, as shown in FIG. 13, the touch sensing driving signal STH is not synchronized with the horizontal synchronization signal Hsync or the vertical synchronization signal Vsync, but it is operated by the long horizontal blanking interval LHB of the horizontal synchronization signal Hsync during the display period. At this time, the cathode electrode CE formed of the first conductive layer or the anode electrode AE formed of the second conductive layer can be maintained at a fixed voltage, but not limited to this.

In a practical application, the touch sensing period of the in-cell capacitive touch panel of the invention can at least partially overlap with the display interval of the display period, as shown in FIG. 12 and FIG. 13.

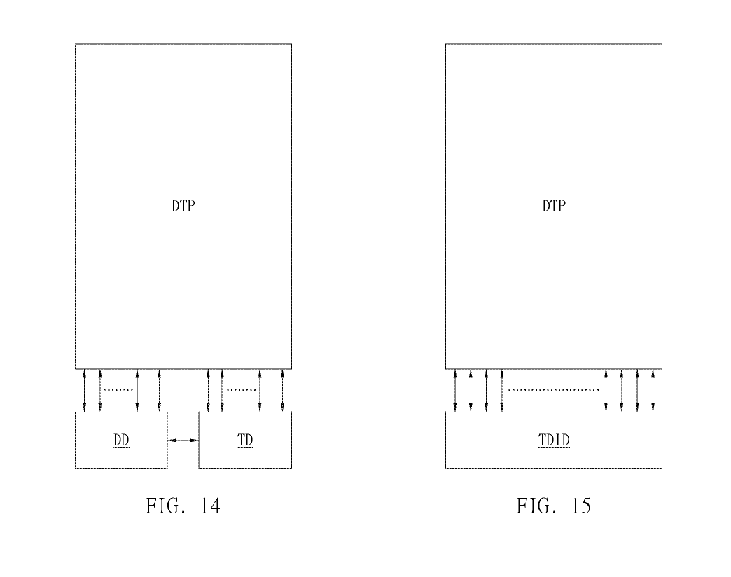

Then, please refer to FIG. 14 and FIG. 15. FIG. 14 illustrates a schematic diagram of the display and touch operations of the in-cell capacitive touch panel separately controlled by the display driver DD and the touch driver TD; FIG. 15 illustrates a schematic diagram of the display and touch operations of the in-cell capacitive touch panel controlled by the touch display integrated driver (TDID).

As shown in FIG. 14, the in-cell capacitive touch panel DTP is coupled to the contact controller TD and the display controller DD respectively, and the touch controller TD synchronizes with the display controller DD and adjusts the timing of the touch and display operations.

As shown in FIG. 15, the in-cell capacitive touch panel DTP is coupled to the touch control display controller (e.g., the touch display integrated driver) TDID. The touch display integrated driver is integrated by the touch controller and the display controller, and it is used to adjust the timing of the touch and display operations.

Compared to the prior art, the in-cell capacitive touch panel of the invention is suitable for a passive matrix organic light-emitting diode display, and can effectively integrate display and touch functions, and the in-cell capacitive touch panel of the invention has the following advantages:

(1) The design of the touch sensing electrode and its traces is relatively simple, and can be applied to mutual-capacitive touch sensing technology or self-capacitive touch sensing technology.

(2) The original conductive layer in the panel can be used as touch electrodes to reduce the complexity of manufacturing process and the manufacturing cost.

(3) The overlapping area of the touch sensing electrode and the display driving electrode is relatively small, which can effectively reduce the RC loading of the panel and reduce noise.

(4) The touch sensing electrode system is disposed between pixels, so the display area of the pixel is not blocked, and the influence on the visibility of the panel can be reduced.

(5) Touch and display can be driven in a time-dividing way to improve the signal-to-noise ratio.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An in-cell capacitive touch panel, applied to a passive matrix light-emitting diode display, the in-cell capacitive touch panel comprising:
a plurality of pixels, a laminated structure of a pixel of the plurality of pixels comprising;
a substrate, disposed at one side of the pixel;
a first conductive layer, disposed above the substrate and arranged along a first direction;
a second conductive layer, disposed above the first conductive layer and arranged along a second direction; and
a LED layer, disposed between overlapping regions of the first conductive layer and the second conductive layer to form the pixel; and
a first touch electrode, disposed between a first pixel and a second pixel of the plurality of pixels, wherein the first pixel and the second pixel are adjacent.

2. The in-cell capacitive touch panel of claim 1, wherein the laminated structure further comprises:
an encapsulation layer, disposed on another side of the pixel opposite to the substrate; and
an insulating layer, filled between the encapsulation layer and the substrate.

3. The in-cell capacitive touch panel of claim 2, further comprising:
a second touch electrode, disposed between the first pixel and a third pixel of the plurality of pixels, wherein the first pixel and the second pixel are adjacent to each other along the second direction, and the first pixel and the third pixel are adjacent to each other along the first direction.

4. The in-cell capacitive touch panel of claim 3, wherein the first touch electrode and the second touch electrode are disposed between the encapsulation layer and the substrate, and the second touch electrode is disposed above the first touch electrode and the first conductive layer, the first touch electrode and the second conductive layer are separated by the insulating layer and the second touch electrode and the first conductive layer are separated by the insulating layer.

5. The in-cell capacitive touch panel of claim 4, wherein the first touch electrode and the second touch electrode are electrically connected through a via to form a mesh structure or a comb structure.

6. The in-cell capacitive touch panel of claim 3, wherein the first touch electrode and the second touch electrode are disposed between the encapsulation layer and the substrate, and the first touch electrode and the second touch electrode are formed of the same conductive layer and electrically connected to each other, the first touch electrode and the second touch electrode are separated from the second conductive layer and the first conductive layer through the insulating layer.

7. The in-cell capacitive touch panel of claim 2, wherein the first pixel and the second pixel are adjacent to each other along the first direction or the second direction, and the first touch electrode is disposed between the encapsulation layer and the substrate.

8. The in-cell capacitive touch panel of claim 7, wherein the first touch electrode and the first conductive layer are formed of the same conductive layer and separated from each other through the insulating layer.

9. The in-cell capacitive touch panel of claim 7, wherein the first touch electrode and the second conductive layer are formed of the same conductive layer and separated from each other through the insulating layer.

10. The in-cell capacitive touch panel of claim 7, wherein the first touch electrode is formed of a conductive layer different from the first conductive layer and the second conductive layer and the first touch electrode is separated from the first conductive layer and the second conductive layer through the insulating layer.

11. The in-cell capacitive touch panel of claim 7, wherein a plurality of first touch electrodes are arranged as an one-dimensional self-capacitive touch sensing electrode group having a specific pattern to determine a touch position through a self-capacitance sensed by a first touch electrode or a ratio of the self-capacitances sensed by two adjacent first touch electrodes.

12. The in-cell capacitive touch panel of claim 1, wherein the light emitting diode layer is formed of an organic light-emitting diode (OLED) in each of the plurality of pixels.

13. The in-cell capacitive touch panel of claim 1, wherein the light emitting diode layer is formed of a micro light-emitting diode (Micro LED) in each of the plurality of pixels.

14. The in-cell capacitive touch panel of claim 1, wherein the light emitting diode layer is formed of an organic light-emitting diode (OLED) in a part of the plurality of pixels, and the light emitting diode layer is formed of a micro light-emitting diode (Micro LED) in another part of the plurality of pixels.

15. The in-cell capacitive touch panel of claim 3, wherein the first conductive layer forms a plurality of first polarity electrodes arranged in parallel, and the plurality of first polarity electrodes are coupled to a first polarity driver, the first touch electrode is disposed in a gap between two first polarity electrodes of the plurality of first polarity electrodes.

16. The in-cell capacitive touch panel of claim 3, wherein the second conductive layer forms a plurality of second polarity electrodes arranged in parallel, and the plurality of second polarity electrodes are coupled to a second polarity driver, the second touch electrode is disposed in a gap between two second polarity electrodes of the plurality of second polarity electrodes.

17. The in-cell capacitive touch panel of claim 3, wherein the first touch electrode and the first conductive layer are formed of the same conductive layer or different conductive layers.

18. The in-cell capacitive touch panel of claim 3, wherein the second touch electrode and the second conductive layer are formed of the same conductive layer or different conductive layers.

19. The in-cell capacitive touch panel of claim 1, wherein a mutual-capacitive touch sensing technology or a self-capacitive touch sensing technology is applied to the in-cell capacitive touch panel.

20. The in-cell capacitive touch panel of claim 1, wherein the light emitting diode layer has a top-emitting light-emitting diode structure, a bottom-emitting light-emitting diode structure or a double-sided light-emitting diode structure.

21. The in-cell capacitive touch panel of claim 3, wherein a touch sensing mode and a display mode of the in-cell capacitive touch panel are driven in a time-dividing way, so that a touch sensing period and a display period of the in-cell capacitive touch panel do not overlap each other.

22. The in-cell capacitive touch panel of claim 21, wherein when the in-cell capacitive touch panel operates under the touch sensing mode in a blanking interval out of the display period, the first conductive layer or the second conductive layer of the pixel is maintained at a fixed voltage.

23. The in-cell capacitive touch panel of claim 22, wherein the blanking interval comprises at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval comprises the vertical blanking interval.

24. The in-cell capacitive touch panel of claim 3, wherein the touch sensing period and the display period of the in-cell capacitive touch panel are at least partially overlapped.

25. The in-cell capacitive touch panel of claim 24, wherein when the in-cell capacitive touch panel is synchronized with a horizontal sync signal or a vertical sync signal or operates under the touch sensing mode in a blanking interval out of the display period, the first conductive layer or the second conductive layer of the pixel is maintained at a fixed voltage.

26. The in-cell capacitive touch panel of claim 25, wherein the blanking interval comprises at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval comprises the vertical blanking interval.

27. The in-cell capacitive touch panel of claim 3, wherein the in-cell capacitive touch panel is coupled to a touch controller and a display controller respectively, and the touch controller is synchronized with the display controller to adjust a timing of touch and display operations.

28. The in-cell capacitive touch panel of claim 3, wherein the in-cell capacitive touch panel is coupled to a touch display controller, and the touch display controller is formed by integrating a touch control and a display controller to adjust a timing of touch and display operations.
